(19) United States
(12) Patent Application Publication
(10) Pub. No.: US 2006/0202298 A1
(43) Pub. Date: Sep. 14, 2006

(54) Device produced by method for etching a layered substrate

(76) Inventor: Karen T. Signorini, Boise, ID (US)

Correspondence Address: Michael G. Fletcher;FLETCHER YODER, P.O. Box 692289, Houston, TX, 77269-2289, US

(21) Appl. No.: 11/436,151

(22) Filed: May 17, 2006

Related U.S. Application Data
(62) Division of application No. 10/230,593, filed on Aug. 29, 2002.

(51) Int. Cl. H01L 31/0232

(52) U.S. Cl. 257/437; 257/E21.029

(57) ABSTRACT

A device made through a fabrication method is disclosed. In one embodiment, the method includes a dry etch plasma process that utilizes CO₂ to etch a layer. Furthermore, the dry etch plasma process may utilize CO₂ in combination with NH₃, H₂, Ar, N₂, He, or other inert gases during the etching process. In another embodiment, the CO₂ dry etch plasma process etches an anti-reflectant coating layer while enabling greater selectivity and control with regard to underlying layers.

### CROSS-REFERENCE TO RELATED APPLICATION

This application is a divisional of U.S. patent application Ser. No. 10/230,593, which was filed on Aug. 29, 2002.

### BACKGROUND OF THE INVENTION

1. Field of the Invention

The present invention relates generally to a method of manufacturing integrated circuits and, more particularly, to a method of etching anti-reflectant coating layers.

2. Background of the Related Art

This section is intended to introduce the reader to various aspects of art, which may be related to various aspects of the present invention, which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Microprocessor-controlled circuits are used in a wide variety of applications throughout the world. Such applications include personal computers, control systems, telephone networks, and a host of other consumer products. A personal computer or control system is made up of various different components that handle different functions for the overall system. By combining these different components, various consumer products and systems are able to meet the specific needs of an end user. As is well known, microprocessors are essentially generic devices that perform specific functions under the control of software programs. These software programs are generally stored in one or more memory devices that are coupled to the microprocessor and/or other peripherals.

The memory devices include many different types of circuits that are typically formed using semiconductor material. These circuits work together to allow the memory device to carry out and control various functions within an electronic device. One type of high-density memory device is a random access memory (RAM) device. The random access memories are complex integrated circuits, which are fabricated using a variety of designs. Despite their complexity, manufacturers typically attempt to design memories that are inexpensive to manufacture, while at the same time maintain high performance and high reliability.

Random access memory devices, such as dynamic random access memory (DRAM) devices and static random access memory (SRAM) devices, generally include a number of memory cells arranged in an array of rows and columns. The rows and columns provide signal paths to and from each memory cell in the array. Regardless of whether the device is a DRAM or SRAM, each memory cell generally includes one or more storage devices, such as capacitors, and one or more access devices, such as transistors. The access devices are generally coupled to the rows and columns of the array to provide access to the storage device.

Integrated circuits, such as memory devices, are typically fabricated on a wafer surface through any number of manufacturing processes, such as layering, doping, and patterning. Layering generally refers to adding material to the surface of the wafer by a growth process, such as oxidation, or through a deposition process, such as chemical vapor deposition (CVD) or physical vapor deposition (PVD). Doping generally refers to the process of implanting dopants into the wafer surface or overlying layer and may be used to increase the current carrying capacity of a region of the wafer or overlying layer of material. The doping process may be implemented before a layer is formed, between layers, or even after the layer is formed. Generally, the doping process may be accomplished through an ion implantation process, using boron or other similar dopants, or through thermal diffusion, for example.

Patterning refers to a series of steps that result in the removal of selected portions of layers or underlying wafer material. After removal of the selected portions of the layer(s), via a wet or dry etch process, a pattern is left on the wafer surface. The removal of material allows the structure of the device to be formed by providing holes or windows between layers or by removing unwanted layers. Patterning sets the critical dimensions of the integrated circuit structures being fabricated. Disadvantageously, errors in the patterning and removal process may result in changes and failures in the electrical characteristics in the device.

One commonly used patterning technique is photolithography. In implementing photolithography techniques, a pattern may be formed by using a photomask to expose certain regions of a radiation sensitive material, such as a photoresist or resist, to a certain wavelength of light. Typically, the radiation source provides UV light to pattern the resist. However certain resists may also be implemented using other energy types, such as X-rays. Exposure to the radiation changes the structure of the resist. If the resist is a negative resist, then the resist becomes polymerized where it is exposed. If the resist is a positive resist, the exposed region of resist becomes divided or softened. After the exposure to the radiation, the unpolymerized regions may be dissolved by applying an appropriate solvent. In this process optical diffraction or optical phase shifting in the photomask may be used to enhance the process.

To fabricate an appropriately sized structure, an anti-reflectant coating (ARC) layer, such as a bottom anti-reflectant coating (BARC) layer discussed herein by way of example, may be implemented underneath the resist to enhance the photolithography process. The BARC layer is used to absorb the radiation generated by the energy source. By providing a layer for absorbing the radiation, the patterned structure is typically more defined with fewer defects than the methods wherein a BARC layer is not included. Once the resist has been patterned, the resist layer may be removed to allow the underlying structure to be developed. While it may be desirable to retain the BARC layer, it is typically desirable to remove the BARC layer through an etching process.

In etching the BARC layer, selective etchants may be implemented to remove the photoresist layer and/or underlying layers simultaneously. A high selectivity means that one layer will be etched at a faster rate in comparison to another layer. Thus, an etchant having a high selectivity to the BARC layer compared to underlying layers indicates that the BARC layer will be etched quicker than the underlying layer or layers. Similarly, the etchant may also have a higher selectivity to the BARC layer than the photoresist such that the BARC layer etched at a faster rate than the photoresist. In the BARC etching process, it may be desirable to select an etchant that enables the process to maintain uniformity and control. Thus, the etchant used may be a 1:1 etchant with respect to the resist and the BARC layer. This allows the etchant to remove the BARC layer at relatively the same rate that the resist is removed. Similarly, a process may be used to etch through the underlying layers in addition to the BARC layer or may be used to remove the BARC layer completely before any of the underlying layers or substrate is etched. If the process is not intended to etch the layers underlying the BARC layer, an etchant having a high selectivity between the BARC layer and the underlying material may be implemented.

To etch the BARC layer, a dry etch plasma including fluorine or nitrogen compounds or 0₂ is typically implemented. However, in using these types of etchants, limitations with regard to the selectivity of the underlying materials present certain problems. For example, the addition of 0₂ to the etchant tends to etch isotropically, i.e. the etchant removes material laterally as well as perpendicularly. Thus, the 0₂ etchants tend to undercut the structure being formed by the etching process. Similarly, with a fluorine compound, the selectivity is generally lower than other etchants. Thus, a fluorine compound etching process of the BARC layer may etch the underlying layers at a faster rate than may be desired. With the fluorine compound's lower selectivity, fewer materials have a high resistance to the etching, which may limit the materials that may be used under the BARC unless an etch stop layer is added. In either situation, the cost of the overall system may be increased or the definition in the critical dimensions of the structure may be reduced.

Another alternative method of etching the BARC layer is to dispose extra resist, which may be removed during the etching process. The larger resist allows the etchant to simultaneously remove the resist and the BARC layer. Disadvantageously, this approach uses more resist to ensure that some resist is present through completion of the etching process. The additional resist increases the overall cost for the process. Likewise, any deformations in the patterned resist may be passed to the underlying material in the structure being formed. Thus, this approach increases the potential risk for flaws in the device.

### BRIEF DESCRIPTION OF THE DRAWINGS

Advantages of the invention may become apparent upon reading the following detailed description and upon reference to the drawings in which:

FIGS. 1-3 illustrate an exemplary process for patterning an exemplary bottom anti-reflectant coating layer in accordance with the present techniques.

### DESCRIPTION OF SPECIFIC EMBODIMENTS

One or more specific embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

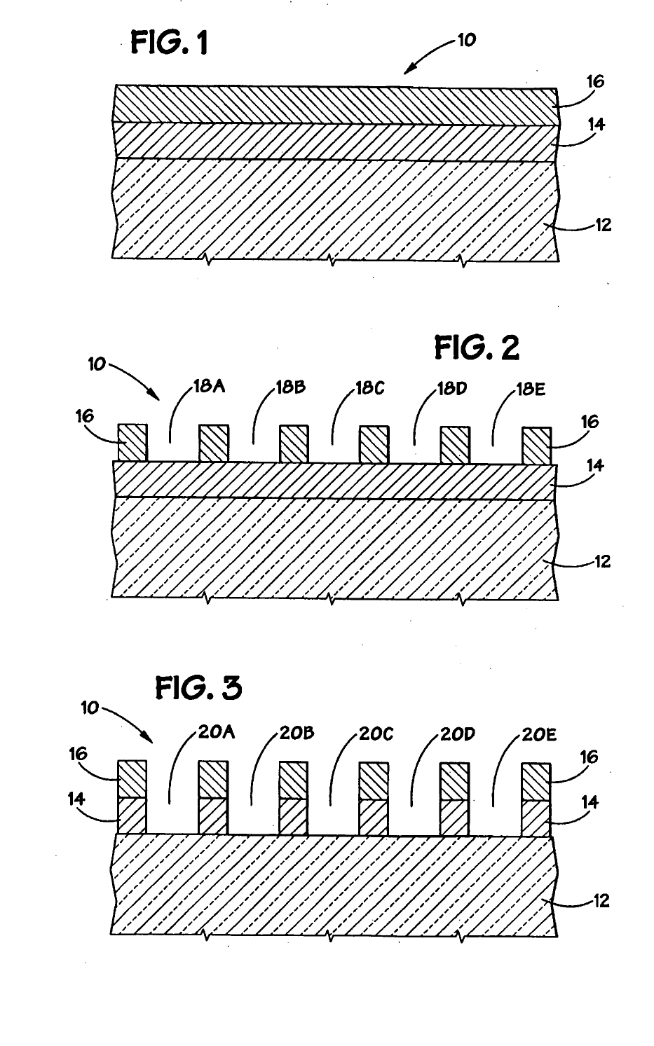

Turning to the drawings, FIG. 1 is a cross sectional view of a device 10, such as an integrated circuit, during the fabrication process. To pattern sections of a substrate 12, an anti-reflectant (ARC) layer, such as a bottom anti-reflectant coating (BARC) layer 14, and a photoresist 16 are disposed over the substrate 12. The substrate 12 may be a semiconductor wafer, photomask blank, dielectric foundation, etc. Similarly, the substrate 12 may include one or more layers of dielectric, conductor, semiconductor, or combinations thereof. Furthermore, other layers may be added or removed, as the fabrication process may include the combination of multiple layers of material.

The BARC layer 14 may be formed by any suitable technique, such as plasma enhanced chemical vapor deposition, chemical vapor deposition, or physical vapor deposition. In one example, the BARC layer is organic and may be disposed onto the wafer via a spinning process. The thickness of the BARC layer 14 may vary depending on the selected process. For example, in one embodiment, the bottom anti-reflectant coating 14 may have a thickness of about 600 angstroms and typically comprises an anti-reflectant material, such as AR3 or DUV42P, for example. As previously described, the BARC layer 14 is disposed below the photoresist 16 to mitigate the effects of reflective development of the underside of the photoresist 16, as can be appreciated by those skilled in the art.

After deposition of the BARC layer 14, the photoresist layer 16 may be disposed over the BARC layer 14 via a spin process, for example. The photoresist 16 may be selective to any one of a number of energies having a corresponding wavelength, or specifically designed for use with an ultra-violet energy source of 193 nanometer or smaller, for example. The photoresist 16 may include any suitable photoresist material.

To form the photoresist 16 into a mask layer, radiation is generated from a light or energy source that is filtered through a photomask and directed at the photoresist layer 16. The mask allows the radiation to impact the photoresist 16 at selected areas, thereby changing the structure of the photoresist 16. The radiation generated from the source may be a UV light or an X-ray, for example. Specifically, the wavelength of the radiation may be 193 nanometers or less. The changes in the photoresist 16 vary depending on the type of photoresist implemented. If the photoresist 16 is a negative resist, the photoresist 16 may become polymerized where it is exposed to the radiation. If the photoresist 16 is a positive resist, then the exposed region may become divided or softened, while the unexposed portion remains polymerized. In this process, optical diffraction or optical phase shifting in the photomask may be used to enhance the process, as can be appreciated by those skilled in the art.

After the exposure to the radiation, the softened regions of the photoresist 16 may be dissolved by applying an appropriate solvent. The solvents that may be used to dissolve the photoresist 16 may include a fluorine compound or an acidic compound, for example. After the development and dissolution of the photoresist 16 is complete, the patterned photoresist 16 may form windows 18A-18E in the photoresist 16 as illustrated in FIG. 2. The windows 18A-18E may expose all, none, or a portion of the BARC 14. In the present embodiment, the pattern developed exposes areas of the BARC 14 through the windows 18A-18E thereby enabling the subsequent etching of the exposed areas.

FIG. 3 illustrates the device 10 after the BARC 14 has been selectively etched through the windows 18A-18E. The result of the BARC layer 14 etching process is the formation of the windows 20A-20E to the surface of the substrate 12. These windows 20A-20E may expose all, none, or a portion of the underlying substrate 12 in the same pattern that has been formed into the photoresist 16 and the BARC 14. The process for etching the BARC 14 may be used to allow the underlying substrate 12 to be fabricated further. The etching process may include a wet etch process, a dry etch process, or any other conventional process, as can be appreciated by those skilled in the art.

One specific method used to etch the BARC 14 may be a dry etch plasma process. In using the dry etch plasma process, dry plasma etchants are used to remove the portion of unprotected BARC 14 that is exposed through the windows 18A-18E illustrated in FIG. 2. As previously described, typical etchants such as fluorine, oxygen and nitrogen may reduce the definition of the fabricated structures. Advantageously, the present techniques implement a CO₂ compound either alone or in combination with other gases as the dry plasma etchant. The CO₂ may be used with at least one other gas in this process, such as NH₃, H₂, Ar, N₂, He, inert gases, or other gases that have suitable properties.

By utilizing CO₂ in the dry etch plasma process, the underlying substrate 12 may not be affected during the etching of the BARC 14 since a variety of dry plasma etchants may be selected which do not react with the underlying material of the substrate 12. While the CO₂ etchant is typically slower than O₂, this reduced speed enables greater control over the depth to which the underlying bottom anti-reflectant coating 14 will be etched. In addition to more control of the etch rate, the CO₂ etchant is better suited for maintaining the critical dimensions of the structure being fabricated. Advantageously, the CO₂ etchant does not damage the lateral walls of the BARC 14 and photoresist 16 layers as much as other etchants that etch more anisotropically. The CO₂ etchant forms a polymer in the BARC 14 and photoresist 16 while it etches. The formation of the polymer prevents the lateral walls of the structure from being damaged during the etching process. Furthermore, etching with CO₂ allows for greater selectivity than is available with typical etchants such as fluorine. Thus, the dry etch plasma process has more flexibility and improves selectivity, while more accurately retaining the patterned lateral structure.

The dry etch plasma process may include various different elements and steps. The settings for these elements and steps depend on the various embodiments of the underlying device 10. One exemplary embodiment may include NH₃ combined with the C0₂. In this embodiment, the chamber pressure may in the range of about 4 to about 100 millitorr and, more specifically, about 5 millitorr. The plasma generator may operate in the range of at about 100 to about 1500 watts and, more specifically, about 500 watts. The substrate may be biased by a source in the range of about 50 watts to about 550 watts and, more specifically, at about 100 watts. In addition, the flow rate of the CO₂ may be between about 1 and about 50 standard cubic centimeters per minute (sccm). More specifically, a CO₂ flow rate of about 5 sccm may be implemented. The flow rate of the NH₃ may be between about 5 and about 100 sccm. In one exemplary embodiment, the flow rate setting of the NH₃ is about 40 sccm. The duration of the etching process may take from about 5 seconds to about 100 seconds. For example, for a CO₂/NH₃ process, an etch duration of about 30 seconds may be implemented.

As an alternative method, another embodiment may utilize Argon (Ar) combined with the C0₂. In this embodiment, the chamber pressure may be in a range from about 3 to about 100 millitorr. Specifically, the chamber pressure may be about 5 millitorr. The plasma generator may operate in the range of about 100 to about 1500 watts and, more specifically, at about 500 watts. The substrate may be biased by a source in the range of about 100 watts to about 500 watts and, more specifically, at about 250 watts. In addition, the flow rate of the CO₂ may be between about 1 and about 50 standard cubic centimeters per minute (sccm). More specifically, the flow rate setting for the CO₂ may be about 10 sccm. The flow rate of the Argon (Ar) gas may be between about 5 and about 75 sccm. In one exemplary embodiment, the Argon (Ar) gas may have a flow rate of about 40 sccm. The duration of the etching process may be from about 5 to about 100 seconds and, more specifically, about 30 seconds, for example.

Furthermore, another possible embodiment may utilize N₂ combined with the C0₂. In this embodiment, the chamber pressure may be in a range from about 3 to about 100 millitorr. Specifically, the chamber pressure may be about 5 millitorr. The plasma generator may operate in the range of about 100 watts to about 1500 watts and, more specifically, at about 750 watts. The substrate may be biased by a source in the range of about 100 watts to about 500 watts, or more specifically, at 250 watts. In addition, the flow rate of the CO₂ may be between about 1 and about 50 standard cubic centimeters per minute (sccm). More specifically, the flow rate for the CO₂ may be about 10 sccm. The flow rate of the N₂ may be between about 5 sccm and about 75 sccm. Specifically, the flow rate setting of the N₂ may be 40 sccm. The duration of the etching process may be from about 5 to about 100 seconds and, more specifically, about 30 seconds, for example.

In addition to etching the BARC layer 14, the etching process may be used to etch through other layers of the substrate 12, as well. The BARC layer 14 may be etched in combination with the layers, such as the substrate 12, an underlying structure, a metal layer, or a dielectric layer. In this embodiment, the substrate 12 may include a wafer having a metal layer disposed thereon. The etchant utilized in this process may be a 1:1 etchant, which etches the BARC layer 14 at the same rate as the metal layer but has a high selectivity with respect to the photoresist 16. Similarly, in another embodiment, the substrate 12 may include a dielectric layer. The etchant in this process may etch the dielectric layer and BARC 14 at the same rate while etching the photoresist layer 16 at a slower rate. The selection etchant may be adjusted in view of the underlying material to produce a desired result in accordance with the present techniques.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A device comprising:
an organic bottom anti-reflectant coating layer disposed over a substrate, the bottom anti-reflectant coating layer having a plurality of openings formed through a dry etch plasma process utilizing a CO₂ etchant either alone or in combination with only one other gas.

2. The device, as set forth in claim 1, wherein the one other gas is an inert gas.

3. The device, as set forth in claim 1, wherein the one other gas is NH₃.

4. The device, as set forth in claim 1, wherein the one other gas is H₂.

5. The device, as set forth in claim 1, wherein the one other gas is Ar.

6. The device, as set forth in claim 1, wherein the one other gas is N₂.

7. The device, as set forth in claim 1, wherein the one other gas is He.

8. The device, as set forth in claim 1, wherein the substrate comprises a metal layer.

9. The device, as set forth in claim 1, wherein the substrate comprises a dielectric layer.

10. The device, as set forth in claim 1, wherein the substrate comprises a semiconductor layer.

11. The device, as set forth in claim 1, wherein the dry etch plasma process utilizes the CO₂ etchant without any other gas.

12. An integrated circuit fabricated via a method comprising:
disposing an organic bottom anti-reflectant coating layer on a substrate;
disposing a photoresist layer on the organic bottom anti-reflectant coating layer;
patterning the photoresist layer; and
etching the organic bottom anti-reflectant coating layer using a dry plasma etch process, the dry plasma etch process utilizing CO₂ either alone or in combination with only one of NH₃, H₂, or an inert gas to pattern the organic bottom anti-reflectant coating layer.

13. The integrated circuit, as set forth in claim 12, wherein the substrate comprises an additional layer, wherein the additional layer comprises at least one of a metal layer, a dielectric layer, or a semiconductor layer.

14. The integrated circuit, as set forth in claim 13, wherein the method comprises etching the additional layer of the substrate.

15. The integrated circuit, as set forth in claim 14, wherein the method comprises removing the organic bottom anti-reflectant coating layer from the substrate.

16. The integrated circuit, as set forth in claim 12, wherein the inert gas is one of Ar, N₂, or He.

17. The integrated circuit, as set forth in claim 12, wherein the dry etch plasma process utilizes the CO₂ without any other gas.

18. A device produced by a method comprising:
providing a layered substrate; and
etching at least one layer of the layered substrate through a dry plasma etch process, the dry plasma etch process utilizing CO₂ either alone or in combination with only one of NH₃, H₂, or an inert gas to etch the at least one layer.

19. The device, as set forth in claim 18, wherein CO₂ is the only gas used in the dry plasma etch process.

20. The device, as set forth in claim 18, wherein etching the at least one layer comprises patterning the at least one layer for subsequent etching of an additional layer.
